(19) United States
(12) Patent Application Publication
(10) Pub. No.: US 2024/0332224 A1
(43) Pub. Date: Oct. 3, 2024

(54) EMBEDDED MAGNETIC DEVICE INTEGRATED STRUCTURE AND MANUFACTURING METHOD THEREOF

(71) Applicant: Zhuhai ACCESS Semiconductor Co., Ltd, Guangdong (CN)

(72) Inventors: XIANMING CHEN, Guangdong (CN); XIAOWEI XU, Guangdong (CN); YEJIE HONG, Guangdong (CN); BENXIA HUANG, Guangdong (CN); GAO HUANG, Guangdong (CN)

(21) Appl. No.: 18/623,193

(22) Filed: Apr. 1, 2024

(30) Foreign Application Priority Data
Mar. 31, 2023 (CN) 2023103489979

(51) Int. Cl. H10N 50/80; H10N 50/01

(52) U.S. Cl. CPC H01L 23/645

(57) ABSTRACT

An embedded magnetic device integrated structure includes a first insulating layer, a first wiring layer provided on a first surface of the first insulating layer, an element and a magnetic device respectively embedded in the first insulating layer, and a terminal of the element and an electrode of the magnetic device are respectively connected to the first wiring layer, and a second wiring layer provided on a second surface of the first insulating layer and in conductive communication with the first wiring layer via a first conducting post penetrating the first insulating layer. At least one terminal of the element is in conductive communication with at least one electrode of the magnetic device through the first wiring layer.

### CROSS-REFERENCE TO RELATED APPLICATION AND CLAIM OF PRIORITY

This application claims the benefit under 35 USC § 119 of Chinese Patent Application No. 2023103489979 filed on Mar. 31, 2023, in the China Intellectual Property Office, the entire disclosure of which is incorporated herein by reference for all purposes.

### BACKGROUND

### 1. Technical Field

The present disclosure relates to the technical field of semiconductors, and in more particular to an embedded magnetic device integrated structure and a manufacturing method thereof.

### 2. Background of the Invention

With the development of electronic technology, the performance requirements of electronic products are becoming higher, and the size requirements are becoming smaller, so that the high-density integration and miniaturization of packaging substrates and packaging structures of electronic products are inevitable trends. The trend of miniaturization of magnetic elements drives the realization of miniaturization of electronic elements and embedding elements in substrates. Packaging substrates integration technology will become the focus of future development in this field.

### SUMMARY

In view of the above, it is an objective of the present disclosure to provide an embedded magnetic device integrated structure and a manufacturing method thereof.

Based on the above objective, in a first aspect, the present disclosure provides an embedded magnetic device integrated structure, which includes:
a first insulating layer;
a first wiring layer provided on a first surface of the first insulating layer;
an element and a magnetic device respectively embedded in the first insulating layer, and a terminal of the element and an electrode of the magnetic device being respectively connected to the first wiring layer; and
a second wiring layer provided on a second surface of the first insulating layer and in conductive communication with the first wiring layer via a first conducting post penetrating the first insulating layer;
wherein at least one terminal of the element is in conductive communication with at least one electrode of the magnetic device through the first wiring layer.

In a second aspect, embodiments of the present disclosure also provide a manufacturing method of an embedded magnetic device integrated structure, which includes:
(a) providing a bearing board;
(b) forming a coil, an electrode on the coil, a first conducting post, and a sacrificial metal block on the bearing board, wherein the coil extends parallel to the bearing board and the electrode extends perpendicular to the coil;
(c) laminating a sheet-like magnetic material and an insulating material to form a first magnetic layer covering the coil and a second insulating layer covering the first magnetic layer; wherein the coil and the electrode are embedded in the second insulating layer;
(d) thinning the second insulating layer to expose the electrode, the first conducting post and the sacrificial metal block;
(e) removing the bearing board and etching the exposed sacrificial metal block to form a cavity for the embedded element;
(f) forming an adhesive layer on the surface of the second insulating layer exposing the coil, placing an element in the cavity and fixing a terminal of the element via the adhesive layer;
(g) laminating a sheet-like magnetic material and an insulating material on the surface of the second insulating layer exposing the first magnetic layer to form a second magnetic layer on the first magnetic layer and a third insulating layer on the second magnetic layer;
(h) removing the adhesive layer; and
(i) forming a first wiring layer on the surface of the second insulating layer, and forming a second wiring layer on the surface of the third insulating layer; where the first conducting post is used for conductively connecting the first wiring layer and the second wiring layer.

It can be seen from the above that the present disclosure provides a technical solution of an embedded magnetic device integrated structure and a manufacturing method thereof, which realizes an integrated structure of a packaging substrate in which a magnetic device and an element are embedded simultaneously in the same thin insulating layer, realizes the embedding of the same layer of the magnetic device and the element, greatly reduces the thickness of the embedded substrate in which the magnetic device is embedded, simplifies the process flow, improves the production efficiency of a product, reduces the production cost, and realizes refined circuit wiring of the packaging substrate of the embedded magnetic device.

### BRIEF DESCRIPTION OF THE DRAWINGS

In order to more clearly illustrate the technical solutions of the present disclosure or the related art, a brief description will be given below with reference to the accompanying drawings which are required to be used in the description of the embodiments or the related art. It is obvious that the drawings in the description below are only embodiments of the present disclosure, and other drawings can be obtained from these drawings by a person skilled in the art without involving any inventive effort. In the drawings, the thickness and shape of some of the layers and regions may be exaggerated for better understanding and ease of description.

FIGS. 1A-1Q show schematic cross-sectional views of intermediate structures at various steps of a manufacturing method of an embedded magnetic device integrated structure according to an embodiment of the present disclosure;

FIG. 2 is a schematic structural diagram of an embedded magnetic device integrated structure according to an embodiment of the present disclosure.

### DETAILED DESCRIPTION OF THE EMBODIMENTS

The purpose, aspects, and advantages of the present disclosure will become more apparent from the detailed description set forth below when taken in conjunction with the specific embodiments and the appended drawings.

It should be noted that, unless otherwise defined, technical or scientific terms used in the examples of the present application shall have the ordinary meaning as understood by a person skilled in the art to which the present application belongs. The use of the terms “first”, “second”, and the like in the embodiments herein does not denote any order, quantity, or importance, but rather is used to distinguish one element from another. The word “including” or “includes”, and the like, means that the elements or items preceding the word encompass the elements or items listed after the word and equivalents thereof, but do not exclude other elements or items. “Connected” or “coupled” and like terms are not limited to physical or mechanical connections, but may include electrical connections, whether direct or indirect. “Up”, “down”, “left”, “right”, etc. are only used to indicate a relative positional relationship, which may change accordingly when the absolute position of the object being described changes. Unless these terms are used with the terms “immediately” or “directly”, one or more components may be located between two components.

At present, in order to meet the development trend of miniaturization of products, magnetic devices are mainly divided into two types in packaging. One is a conventional and common surface mounting process, with a larger magnetic device and a larger volume after packaging; the other is to embed inside the packaging substrate, which can reduce the volume after packaging; firstly, a magnetic element integrated with a magnet and a metal coil is made and divided into individual devices; then the device is attached to the substrate or the cavity reserved by the packaging substrate by means of a patch, and the packaging is fanned out to realize the development trend of product miniaturization.

However, a magnetic material and metal coil integrated device is manufactured, cut and then mounted with the packaging substrate to realize the embedded substrate structure of the magnetic device, the manufacturing process is long and complicated, and the production cost is high; a single magnetic device is mounted in the cavity of the packaging substrate to perform packaging and fan-out wiring. Since there is a deviation in the connection between the device pin and the wiring of the packaging substrate, the wires of the packaging substrate cannot be refined in wiring.

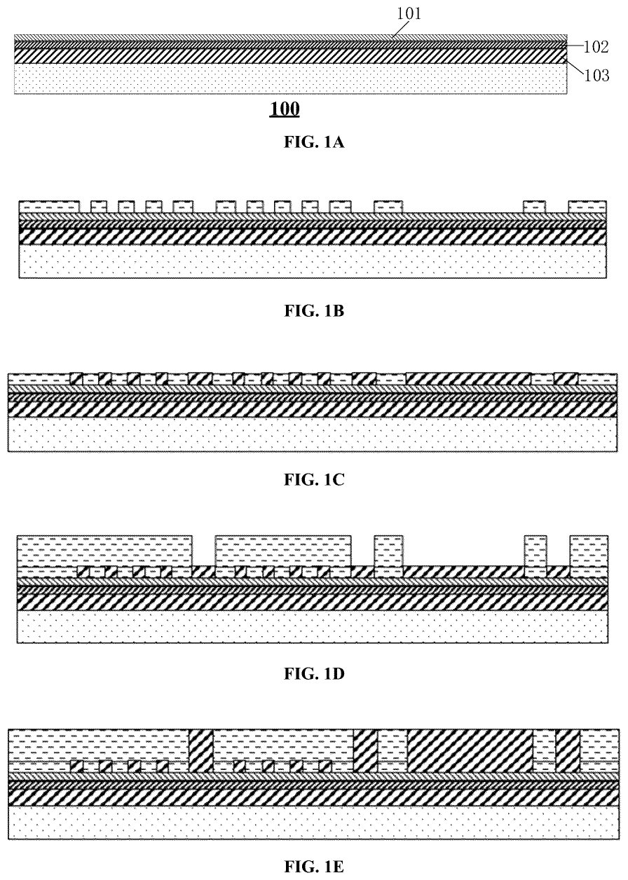

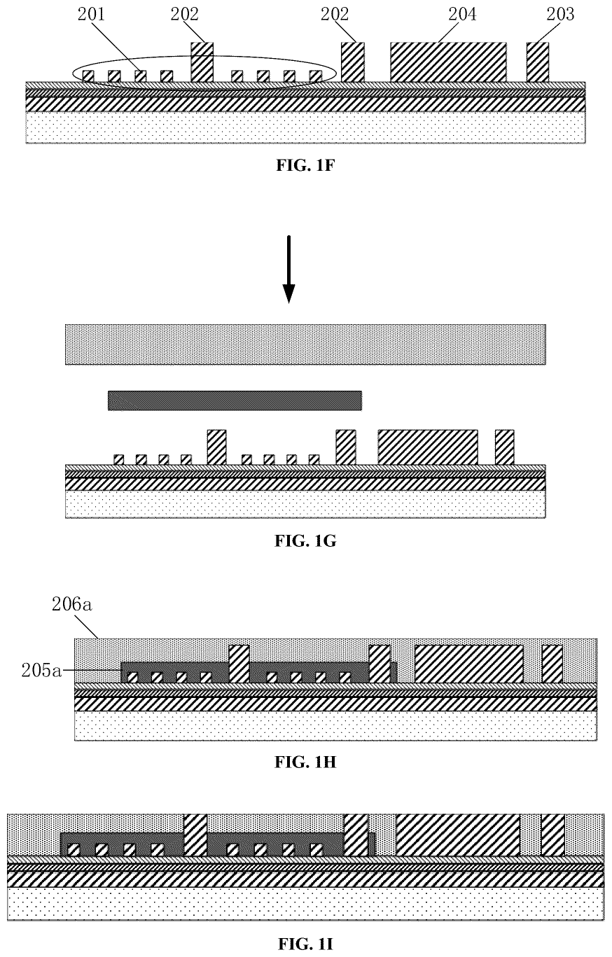

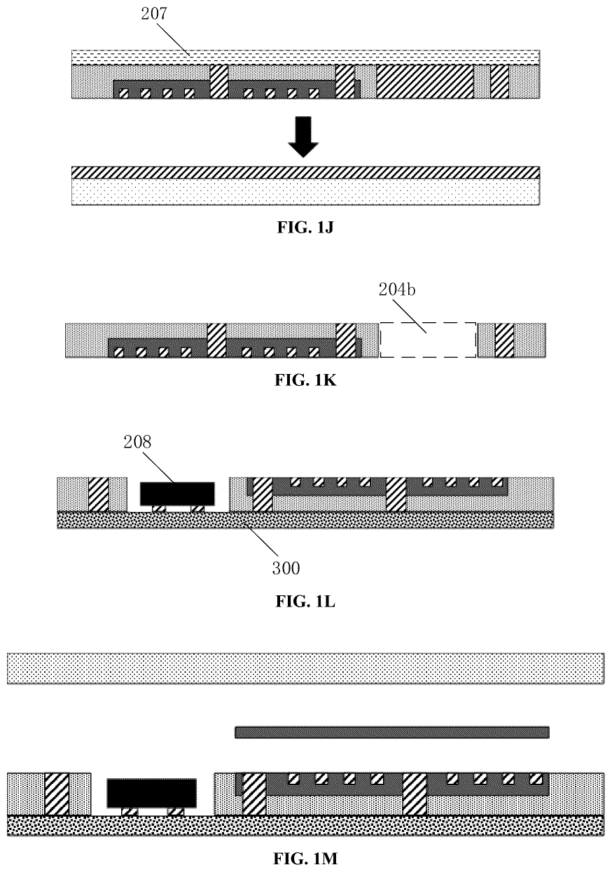

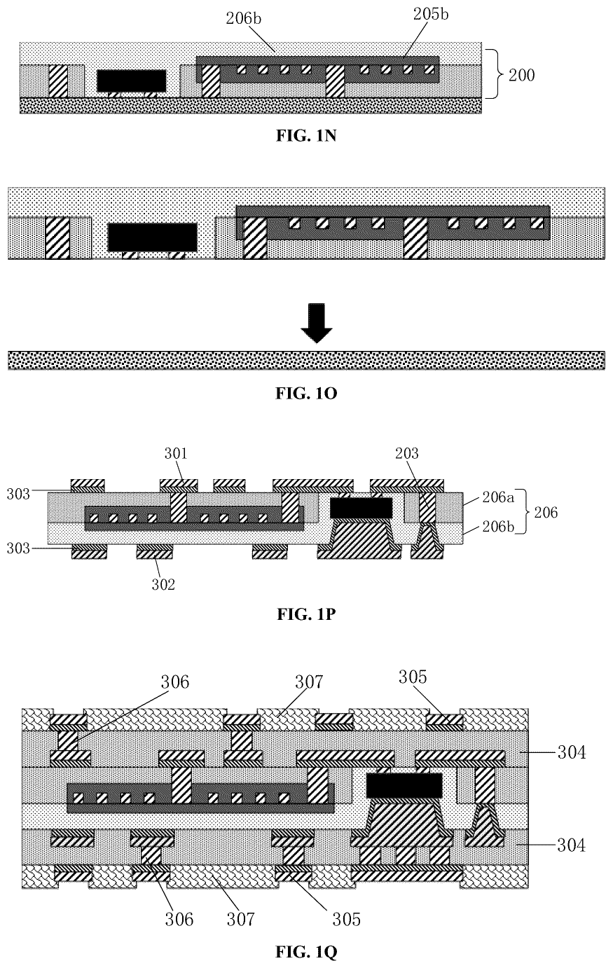

In view of this, a first aspect of an embodiment of the present disclosure provides a manufacturing method of an embedded magnetic device integrated structure. FIGS. 1A-1Q show schematic cross-sectional views of intermediate structures at various steps of a manufacturing method of an embedded magnetic device integrated structure according to an embodiment of the present disclosure.

The manufacturing method includes the steps of: providing a bearing board 100—step (a), as shown in FIG. 1A. The bearing board 100 includes a first seed layer 101, a first metal layer 102 and a second metal layer 103. Alternatively, the first seed layer 101 is made from titanium and the first metal layer 102 and the second metal layer 103 are made from copper.

Alternatively, the first metal layer 102 and the second metal layer 103 are physically bonded to facilitate implementation of a board split process technique.

It should be noted that the first seed layer 101 may be omitted here and formed by deposition when needed (e.g. before step b), and the present disclosure is not limited thereto.

Next, a coil 201, an electrode 202, a first conducting post 203, and a sacrificial metal block 204 are formed on the bearing board 100—step (b), as shown in FIGS. 1B to 1F.

Step (b) is exemplified below with reference to FIGS. 1B to 1F. Specifically, step (b) includes: first, as shown in FIG. 1B, (b1) a first photoresist layer including a first pattern is formed on the first seed layer 101. Here, the first photoresist layer may be formed by coating or laminating a photoresist material, exposing and developing. Next, as shown in FIG. 1C, (b2) the first pattern is electroplating filled to form the coil 201 and part of the electrode, part of the first conducting post, and part of the sacrificial metal block. Then, as shown in FIG. 1D, (b3) a second photoresist layer including a second pattern is formed on the first photoresist layer, and here, the second photoresist layer is formed in a manner similar to that of the first photoresist layer, which will not be described in detail. Next, as shown in FIG. 1E, (b4) the second pattern is electroplating filled to form an electrode 202, a first conducting post 203, and a sacrificial metal block 204. Finally, as shown in FIG. 1F, (b5) the first photoresist layer and the second photoresist layer are removed, such that the coil 201, the electrode 202, the first conducting post 203 and the sacrificial metal block 204 are exposed.

It should be noted that the first pattern and the second pattern differ only in that the first pattern includes a coil pattern. The thickness of the coil 201 is smaller than the height of the electrode 202, the first conducting post 203 and the sacrificial metal block 204, and therefore the first photoresist layer and the second photoresist layer are used to form a corresponding structure by means of two electroplatings, so that the preparation of the magnetic device and the cavity formation step of the embedded element can be performed simultaneously, which helps to shorten the process flow, improve the product production efficiency and reduce the production cost.

Further, the coil 201 extends in a direction perpendicular to the height of the bearing board 100, i.e. the coil 201 extends in the direction of the plane of the bearing board. In this manner, a magnetic device having a flat structure is facilitated to be formed, and the height of the package structure can be effectively reduced to reduce the package volume. At the same time, the coil 201 is formed once to avoid multiple formation of layers, without alignment and with higher accuracy.

Here, the number of coils, the width, and the height of the coil 201 can be adjusted according to actual design requirements, and are not limited thereto.

The electrodes 202 generally extend perpendicularly from the surface of the coil 201, or are conductively connected to the coil 201 extending perpendicularly from the surface of the bearing board 100. Usually, the coil 201 has two electrodes 202, but the coil 201 may also have more than two electrodes 202, in which case the coil length of the magnetic device, and thus the inductance, can be adjusted by electrode cooperation.

Generally, the electrode 202, the first conducting post 203 and the sacrificial metal block 204 have the same height.

Then, the sheet-like magnetic material and the insulating material are laminated to form a first magnetic layer 205a and a second insulating layer 206a—step (c), as shown in FIGS. 1G to 1H. The coil 201 and part of the electrode 202 are embedded in the first magnetic layer 205a; the electrode 202 passes through the first magnetic layer 205a into the second insulating layer 206a. Here, the sheet-like magnetic material is first fixed according to the position covering the coil 201 and the electrode 202, and then the insulating material is stacked; finally, the first magnetic layer 205a and the second insulating layer 206a are formed by lamination.

Alternatively, the second insulating layer 206a is made from a glass fiber-containing resin material such as PP. The use of a glass fiber-containing resin materials helps to increase the rigidity of the product.

Next, the second insulating layer 206a is thinned to expose the electrode 202, the first conducting post 203, and the sacrificial metal block 204—step (d), as shown in FIG. 1I. Alternatively, the thinning process may be mechanical grinding, chemical mechanical grinding or plasma thinning.

Then, the bearing board 100 is removed to expose the coil 201, the electrode 202, the first conducting post 203, the sacrificial metal block 204, the first magnetic layer 205a and the second insulating layer 206a—step (e), as shown in FIG. 1J.

In some embodiments, removing the bearing board 100 specifically includes:
(e1) a third photoresist layer 207 is formed on the second insulating layer; here, the third photoresist layer can protect the electrode 202, the first conducting post 203, from being damaged during subsequent etching of the metal layer.

Alternatively, the third photoresist layer 207 is exposed and developed to expose the sacrificial metal block 204, which may be used directly for subsequent removal of the sacrificial metal block 204.
(e2) the first metal layer 102 and the second metal layer 103 are separated from each other;
(e3) a metal layer, such as the first metal layer 102 and the first seed layer 101, attached on the second insulating layer 206a is etched to expose the coil 201, the electrode 202, the first conducting post 203, the sacrificial metal block 204, the first magnetic layer 205a and the second insulating layer 206a.

Alternatively, if the third photoresist layer 207 does not expose the sacrificial metal block 204, the third photoresist layer needs to be removed.

Next, a fourth photoresist layer is formed on the second insulating layer 206a to expose the sacrificial metal block 204, the sacrificial metal block 204 is etched to form a cavity 204b of the embedded element, and the fourth photoresist layer—step (f) is removed, as shown in FIG. 1K.

It should be noted that if the third photoresist layer 207 exposes the sacrificial metal block 204 by exposure and development, the third photoresist layer can be used as a fourth photoresist layer, and at this time, only the fourth photoresist layer needs to be formed on the other surface of the second insulating layer 206a; otherwise, a fourth photoresist layer needs to be formed on both sides of the second insulating layer 206a in order to protect a coil or the like.

Then, an adhesive layer 300 is formed on the surface of the second insulating layer exposing the coil 201, the element 208 is placed in the cavity 204b and the terminal of the element 208 is adhesively fixed to the adhesive layer 300—step (g), as shown in FIG. 1L. Here, the adhesive layer 300 is used to temporarily secure the element 208.

Here, the element 208 may be an active element (e.g. transistor, IC element, logic circuit element, power amplifier), a passive element (capacitor, inductor, resistor), or a combination thereof. The number of elements 208 is not limited to only one.

Then a sheet-like magnetic material and an insulating material are laminated on the surface of the second insulating layer 206a exposing the first magnetic layer 205a to form a second magnetic layer 205b and a third insulating layer 206b; where the second magnetic layer covers the first magnetic layer 205a—step (h), as shown in FIGS. 1M to IN. Here, the second magnetic layer 205b and the third insulating layer 206b are formed in a manner similar to that of the first magnetic layer and the second insulating layer and will not be described again.

The material of the third insulating layer is a glass fiber-free resin material such as one selected from the group consisting of a liquid crystal polymer, a bismaleimide triazine (BT) resin, a Prepreg, an Ajinomoto Build-up (ABF) film, an epoxy, and a polyimide resin, but the present disclosure is not limited thereto.

Here, a mini-inductor embedded substrate integrated structure 200 is formed through lamination. Here, the first magnetic layer 205a, the second magnetic layer 205b, the coil 201 and the electrode 202 form a mini-inductor.

The adhesive layer 300 is then removed—step (i), as shown in FIG. 10.

The process flow of the embedded magnetic device and the packaging substrate is optimized, and the two manufacturing processes are integrated to form an integrated structure, which can help to reduce the redundant process steps, shorten the process flow, improve the productivity and reduce the production cost.

Then, a wiring layer is formed on the exposed surfaces of the second insulating layer 206a and the third insulating layer 206b; here, the first conducting post 203 is used to connect the wiring layer—step (j), as shown in FIGS. 1P and 1Q.

In some embodiments, step (j) includes:
(j1) a hole is opened on the third insulating layer 206b to expose the back surface of the element and the first conducting post 203; here, a laser opening or a mechanical opening can be used, which is not particularly limited;
(j2) a second seed layer 303 is formed on the exposed surfaces of the third insulating layer 206b and the second insulating layer 206a;
(j3) a fifth photoresist layer including a wire pattern on the second seed layer 303 is formed;
(j4) a wire pattern is electroplating filled, and a first wiring layer 301 is formed on a second insulating layer; a second wiring layer 302 is formed on the third insulating layer;
(j5) the fifth photoresist layer is removed; and
(j6) the second seed layer 303 is etched to obtain the structure as shown in FIG. 1P.

Alternatively, step (j) further includes:
forming a fourth insulating layer 304 on two sides of the first wiring layer 301 and the second wiring layer 302; and forming a third wiring layer 305 on the fourth insulating layer. The conduction mode between the third wiring layer 305 and the first wiring layer 301 and the second wiring layer 302 may include a second conducting post 306, a laser hole conduction or a mechanical hole conduction, etc., which is not specifically limited.

Finally, a solder mask 307 is formed on the third wiring layer 305, and the third wiring layer 305 is exposed through the solder mask opening—step (k), as shown in FIG. 1Q.

With such a technical solution, the embedded magnetic device integrated structure and the packaging substrate reduces the deviation of the electrical connection between the embedded magnetic device and the packaging substrate, improves the fine connection between the terminal and the electrical performance of the packaging substrate, improves the fine wiring capability of the integrated packaging substrate structure of the magnetic device, and effectively improves the product yield.

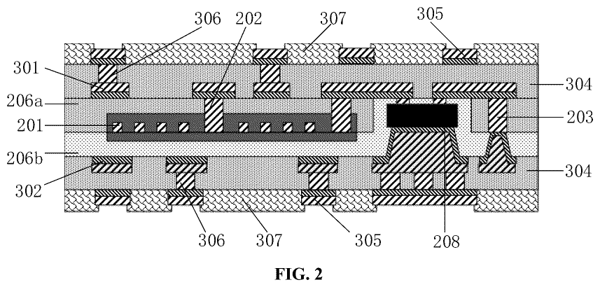

Embodiments of the present disclosure also provide an embedded magnetic device integrated structure that can be prepared by the aforementioned manufacturing method. As shown in FIG. 2, the embedded magnetic device integrated structure includes:
a first insulating layer 206; alternatively, the first insulating layer 206 includes a second insulating layer 206a and a third insulating layer 206b; the second insulating layer 206a and the third insulating layer 206b are made from the same or different materials.

The first wiring layer 301 is provided on a first surface of the first insulating layer 206;
the element 208 and the magnetic device 200 are respectively embedded in the first insulating layer 206, and a terminal of the element 208 and an electrode 202 of the magnetic device are respectively connected to the first wiring layer 301; and
the second wiring layer 302 is provided on a second surface of the first insulating layer 206 and is in communication with the first wiring layer 301 via a first conducting post penetrating the first insulating layer 206; where at least one terminal of the element 208 is in conductive communication with at least one electrode 202 of the magnetic device 200 through the first wiring layer 301.

Alternatively, the second insulating layer 206a located on the element 208 and the terminal side of the magnetic device is a glass fiber-containing resin material; the third insulating layer 206b on the back side of the element 208 and the magnetic device is made from a glass fiber-free resin material. The materials of the second insulating layer 206a and the third insulating layer 206b can be described with reference to the foregoing description of the manufacturing method and will not be described again.

In some embodiments, the magnetic device 200 includes a coil 201; the coil 201 extends in a direction perpendicular to the height of the first insulating layer 206.

In some embodiments, the magnetic device 200 further includes a magnetic layer (e.g. a first magnetic layer and a second magnetic layer) in which the coil 201 is embedded, where the electrodes 202 extend perpendicularly from the coil 201 through the magnetic layer to the first wiring layer 301, the magnetic device 200 including at least two electrodes 202.

In some embodiments, the embedded magnetic device integrated structure further includes:
fourth insulating layers 304 respectively provided on the first wiring layer 301 and the second wiring layer 302; and
third wiring layers 305 respectively provided on the fourth insulating layer 304 and respectively communicating with the first wiring layer and the second wiring layer via a second conducting post 306 penetrating the fourth insulating layer 304.

In some embodiments, the embedded magnetic device integrated structure further includes: a solder mask 307 exposing the third wiring layer 305 through solder mask opening.

The embedded magnetic device integrated structure of the above-described embodiment has the advantageous effects of the aforementioned embodiment of the manufacturing method and will not be described in detail herein.

A person skilled in the art will appreciate that the discussion of any embodiment above is merely exemplary and is not intended to imply that the scope of the present disclosure, including the claims, is limited to these examples; combinations of features in the above embodiments, or between different embodiments, may also be made within the spirit of the present disclosure, the steps may be implemented in any order, and there may be many other variations of the different aspects of the embodiments of the present disclosure as described above, which are not provided in detail for clarity.

The disclosed embodiments are intended to embrace all such alternatives, modifications and variances which fall within the broad scope of the appended claims. Accordingly, it is intended to embrace all such alternatives, modifications, equivalents, improvements, that fall within the spirit and scope of the disclosed embodiments.

What is claimed is:

1. An embedded magnetic device integrated structure comprising:
a first insulating layer;
a first wiring layer provided on a first surface of the first insulating layer;
an element and a magnetic device respectively embedded in the first insulating layer, and a terminal of the element and an electrode of the magnetic device are respectively connected to the first wiring layer; and
a second wiring layer provided on a second surface of the first insulating layer and in conductive communication with the first wiring layer via a first conducting post penetrating the first insulating layer;
wherein at least one terminal of the element is in conductive communication with at least one electrode of the magnetic device through the first wiring layer.

2. The embedded magnetic device integrated structure according to claim 1, wherein the first insulating layer comprises a second insulating layer and a third insulating layer laminated together; wherein the second insulating layer and the third insulating layer are made from the same or different materials.

3. The embedded magnetic device integrated structure according to claim 2, wherein the second insulating layer located at a side of the element and the magnetic device terminal is made from a glass fiber-containing resin material; the third insulating layer located on a back side of the element and the magnetic device is made from a glass fiber-free resin material.

4. The embedded magnetic device integrated structure according to claim 1, wherein the magnetic device comprises a coil, wherein the coil extends in a direction perpendicular to a height of the first insulating layer.

5. The embedded magnetic device integrated structure according to claim 4, wherein the magnetic device further comprises a magnetic layer in which the coil is embedded, wherein the electrode extends perpendicularly from the coil through the magnetic layer to the first wiring layer, the magnetic device comprising at least two electrodes.

6. The embedded magnetic device integrated structure according to claim 1, further comprising:
fourth insulating layers respectively provided on the first wiring layer and the second wiring layer; and
third wiring layers respectively provided on two surfaces of the fourth insulating layer and respectively in conductive communication with the first wiring layer and the second wiring layer via a second conducting post penetrating the fourth insulating layer.

7. The embedded magnetic device integrated structure according to claim 6, further comprising: a solder mask provided on the fourth insulating layer and exposing part of the third wiring layer through a solder mask opening.

8. A manufacturing method of an embedded magnetic device integrated structure, the method comprising:
(a) providing a bearing board;
(b) forming a coil, an electrode on the coil, a first conducting post, and a sacrificial metal block on the bearing board, wherein the coil extends parallel to the bearing board and the electrode extends perpendicular to the coil;
(c) laminating a sheet-like magnetic material and an insulating material to form a first magnetic layer covering the coil and a second insulating layer covering the first magnetic layer; wherein the coil and the electrode are embedded in the second insulating layer;
(d) thinning the second insulating layer to expose the electrode, the first conducting post and the sacrificial metal block;
(e) removing the bearing board and etching the exposed sacrificial metal block to form a cavity for the embedded element;
(f) forming an adhesive layer on a surface of the second insulating layer exposing the coil, placing an element in the cavity, and fixing a terminal of the element via the adhesive layer;
(g) laminating a sheet-like magnetic material and an insulating material on the surface of the second insulating layer exposing the first magnetic layer to form a second magnetic layer on the first magnetic layer and a third insulating layer on the second magnetic layer;
(h) removing the adhesive layer; and
(i) forming a first wiring layer on the surface of the second insulating layer, and forming a second wiring layer on the surface of the third insulating layer; wherein the first conducting post is used for conductively connecting the first wiring layer and the second wiring layer.

9. The manufacturing method according to claim 8, wherein the bearing board further comprises a first seed layer; and
the step (b) comprises:
(b1) forming a first photoresist layer comprising a first pattern on the first seed layer;
(b2) electroplating the first pattern to form the coil and part of the electrode, part of the first conducting post and part of the sacrificial metal block;
(b3) forming a second photoresist layer comprising a second pattern on the first photoresist layer;
(b4) electroplating the second pattern to form the electrode, the first conducting post, and the sacrificial metal block; and
(b5) removing the first photoresist layer and the second photoresist layer.

10. The manufacturing method according to claim 8, wherein at least two electrodes are connected to the coil.

11. The manufacturing method according to claim 8, wherein the second insulating layer is made from a glass fiber-containing resin material.

12. The manufacturing method according to claim 8, wherein the bearing board comprises a first metal layer and a second metal layer laminated; and
the step (e) comprises:
(e1) forming a third photoresist layer on the second insulating layer;
(e2) separating the first metal layer and the second metal layer; and
(e3) etching a metal layer attached to the second insulating layer to expose the coil, the electrode, the first conducting post, the sacrificial metal block, the first magnetic layer and the second insulating layer.

13. The manufacturing method according to claim 8, wherein the third insulating layer is made from a glass fiber-free resin material.

14. The manufacturing method according to claim 8, further comprising:
(j1) laminating a fourth insulating layer on the first wiring layer and the second wiring layer, respectively;
(j2) forming a second conducting post penetrating the fourth insulating layer; and
(j3) forming a third wiring layer respectively on both surfaces of the fourth insulating layer, wherein the third wiring layer respectively conductively connects to the first wiring layer and the second wiring layer through the second conducting posts.

15. The manufacturing method according to claim 14, further comprising:
(k) forming a solder mask on the third wiring layer, and exposing the third wiring layer through a solder mask opening.
